(19) United States
(12) Patent Application Publication
(10) Pub. No.: US 2025/0351552 A1
(43) Pub. Date: Nov. 13, 2025

(54) SEMICONDUCTOR DEVICE

(71) Applicant: FUJI ELECTRIC CO., LTD., Kanagawa (JP)

(72) Inventor: Koh YOSHIKAWA, Matsumoto-city (JP)

(21) Appl. No.: 19/277,320

(22) Filed: Jul. 22, 2025

Related U.S. Application Data
(63) Continuation of application No. PCT/JP2024/024939, filed on Jul. 10, 2024.

(30) Foreign Application Priority Data
Aug. 7, 2023 (JP) 2023-128876

(51) Int. Cl. H10D 84/00; H10D 8/00; H10D 12/00; H10D 62/10; H10D 62/60

(52) U.S. Cl. CPC H10D 84/161; H10D 8/422; H10D 12/481; H10D 62/103; H10D 62/124; H10D 62/60

(57) ABSTRACT

There is provided a semiconductor device (100) including a floating region (202) of a second conductivity type which is arranged below a lower end (43) of a first gate trench portion (40), and which does not extend to a region below a lower end (33) of a first dummy trench portion, at an upper surface side of a semiconductor substrate (10), in which a first mesa portion has an emitter region (12) of a first conductivity type which is provided in contact with the first gate trench portion, and which has a higher concentration than that of a drift region (18), and a base region (14) of the second conductivity type, and the lower end of the first dummy trench portion is in contact with a region of the first conductivity type.

The contents of the following patent application(s) are incorporated herein by reference:
NO. 2023-128876 filed in JP on Aug. 7, 2023
NO. PCT/JP2024/024939 filed in WO on Jul. 10, 2024.

### BACKGROUND

### 1. Technical Field

The present invention relates to a semiconductor device.

### 2. Related Art

In the related art, a semiconductor device provided with a transistor such as an insulated gate bipolar transistor (IGBT) is known (refer to Patent Documents 1 to 4, for example).

### RELATED ART DOCUMENTS

### Patent Documents

Patent Document 1: Japanese Patent No. 6472714
Patent Document 2: Japanese Patent No. 4456013
Patent Document 3: Japanese Patent Application Publication No. 2020-21941
Patent Document 4: Japanese Patent Application Publication No. 2010-232627

### BRIEF DESCRIPTION OF THE DRAWINGS

FIG. 1 is a top plan view showing an example of a semiconductor device 100 according to one embodiment of the present invention.

FIG. 2 shows an enlarged view of a region D in FIG. 1.

FIG. 3 is a view showing an example of a cross section e-e in FIG. 2.

FIG. 4 is a view showing an example of a cross section f-f in FIG. 2.

FIG. 5 is a diagram showing a collector voltage-collector current characteristic, in an Example and a reference example.

FIG. 6 is a diagram showing a measurement example of a voltage and a current of the semiconductor device of an Example.

FIG. 7 is a diagram showing a measurement example of a voltage and a current of the semiconductor device of an Example.

FIG. 8 is a diagram showing another measurement example of the voltage and the current of the semiconductor device of a reference example.

FIG. 9 is a diagram showing another measurement example of the voltage and the current of the semiconductor device of an Example.

FIG. 10 is a diagram showing a trade-off characteristic between a turn-on loss and a reverse recovery dV/dt in a reference example and an Example.

FIG. 11 is a view showing another example of the cross section f-f.

FIG. 12 is a view showing another example of the cross section f-f.

FIG. 13 is a view showing another example of the cross section f-f.

FIG. 14 is a view showing another example of the cross section f-f.

FIG. 15 is a view showing another example of the cross section f-f.

FIG. 16 is a view showing another example of the cross section f-f.

FIG. 17 is a view showing another example of the cross section e-e.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

As used herein, one side in a direction parallel to a depth direction of a semiconductor substrate is referred to as an “upper” side and another side is referred to as a “lower” side. One surface of two principal surfaces of a substrate, a layer, or another member is referred to as an upper surface, and another surface is referred to as a lower surface. “Upper” and “lower” directions are not limited to a direction of gravity, or a direction in which a semiconductor device is mounted.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicating a height direction with respect to the ground. It should be noted that a +Z axis direction and a −Z axis direction are directions opposite to each other. If a Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or /cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

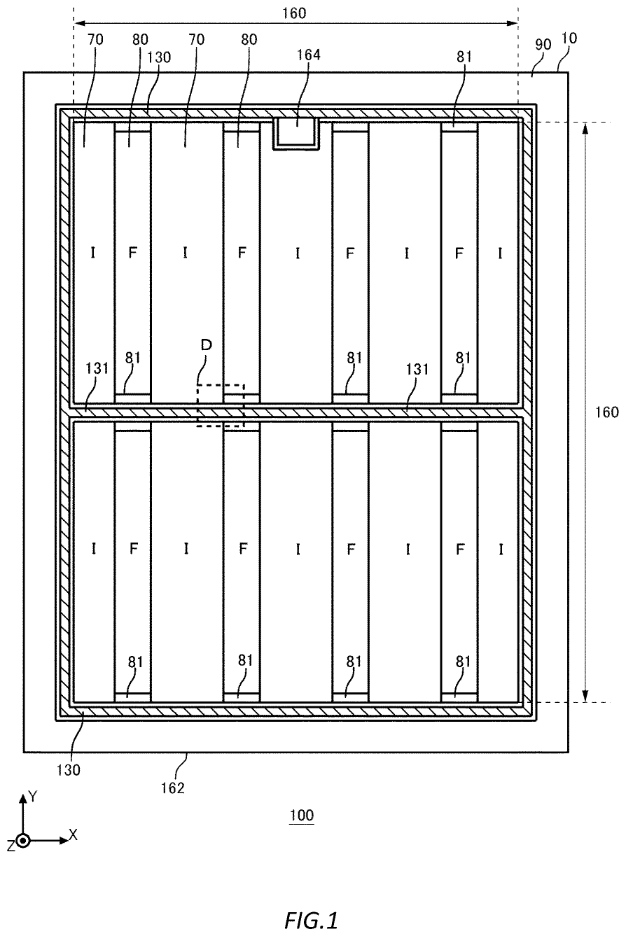

FIG. 1 is a top plan view showing an example of a semiconductor device 100 according to one embodiment of the present invention. FIG. 1 shows a position of each member projected onto an upper surface of a semiconductor substrate 10. In FIG. 1, only some members of the semiconductor device 100 are shown, and illustrations of some members are omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in the present example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but illustration thereof is omitted in FIG. 1. The active portion 160 may refer to a region which overlaps with the emitter electrode in the top view. In addition, a region sandwiched between active portions 160 in the top view may also be included in the active portion 160.

The active portion 160 is provided with transistor portions 70 including transistor elements such as an Insulated Gate Bipolar Transistor (IGBT). The active portion 160 may be further provided with diode portions 80 including diode elements such as a freewheeling diode (FWD). In the example shown in FIG. 1, transistor portions 70 and diode portions 80 are alternately arranged along a predetermined array direction (the X axis direction in the present example) at the upper surface of the semiconductor substrate 10. The semiconductor device 100 in the present example is a reverse conduction type IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extension direction (the Y axis direction in FIG. 1). Each of the transistor portions 70 and the diode portions 80 may have a longitudinal length in the extension direction. In other words, a length of the transistor portion 70 in the Y axis direction is greater than a width in the X axis direction. Similarly, a length of the diode portion 80 in the Y axis direction is greater than a width in the X axis direction. The extension directions of the transistor portion 70 and the diode portion 80, and a longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region which overlaps with the cathode region in the top view. At the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided at a lower surface of the extension region 81.

The transistor portion 70 has the collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged at the upper surface side of the semiconductor substrate 10.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes the gate runner that connects the gate pad 164 to the gate trench portion. In FIG. 1, the gate runner is hatched with diagonal lines.

The gate runner in the present example has an outer peripheral gate runner 130 and an active side gate runner 131. The outer peripheral gate runner 130 is arranged between the active portion 160 and the end side 162 of the semiconductor substrate 10 in the top view. The outer peripheral gate runner 130 in the present example encloses the active portion 160 in the top view. A region enclosed by the outer peripheral gate runner 130 in the top view may be set as the active portion 160. In addition, a well region is formed below the gate runner. The well region is a P type region having a higher concentration than that of the base region described below, and is formed from the upper surface of the semiconductor substrate 10 to a position deeper than that of the base region. A region enclosed by the well region in the top view may be set as the active portion 160.

The outer peripheral gate runner 130 is connected to the gate pad 164. The outer peripheral gate runner 130 is arranged above the semiconductor substrate 10. The outer peripheral gate runner 130 may be a metal wiring line containing aluminum or the like.

The active side gate runner 131 is provided in the active portion 160. Providing the active side gate runner 131 in the active portion 160 can reduce a variation in a wiring line length from the gate pad 164 for each region of the semiconductor substrate 10.

The outer peripheral gate runner 130 and the active side gate runner 131 are connected to the gate trench portion of the active portion 160. The outer peripheral gate runner 130 and the active side gate runner 131 are arranged above the semiconductor substrate 10. The outer peripheral gate runner 130 and the active side gate runner 131 may be a wiring line formed of a semiconductor such as polysilicon doped with an impurity.

The active side gate runner 131 may be connected to the outer peripheral gate runner 130. The active side gate runner 131 in the present example is provided to extend in the X axis direction so as to cross the active portion 160 substantially at the center of the Y axis direction from one outer peripheral gate runner 130 to another outer peripheral gate runner 130 which sandwich the active portion 160. When the active portion 160 is divided by the active side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in the present example includes an edge termination structure portion 90 between the active portion 160 and the end side 162 in the top view. The edge termination structure portion 90 in the present example is arranged between the outer peripheral gate runner 130 and the end side 162. The edge termination structure portion 90 reduces an electric field strength at the upper surface side of the semiconductor substrate 10. The edge termination structure portion 90 may include at least one of a guard ring, a field plate, or a RESURF which are annularly provided to enclose the active portion 160.

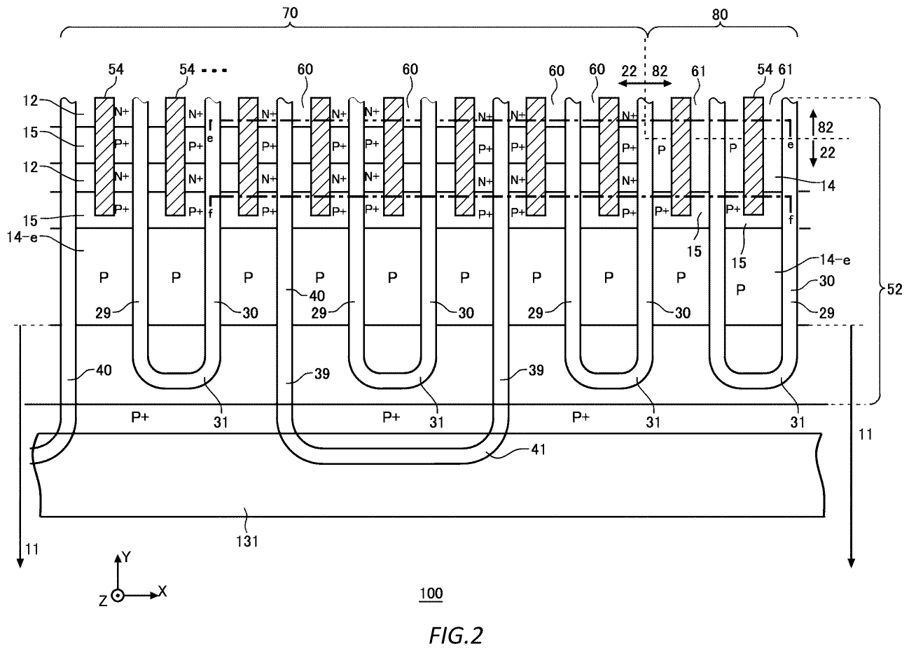

FIG. 2 shows an enlarged view of a region D in FIG. 1. The region D is a region including a transistor portion 70, a diode portion 80, and the active side gate runner 131. The semiconductor device 100 in the present example includes a gate trench portion 40, a dummy trench portion 30, a well region 11, an emitter region 12, a base region 14, and a contact region 15 which are provided inside the upper surface side of the semiconductor substrate 10. Each of the gate trench portion 40 and the dummy trench portions 30 is an example of the trench portion. In addition, the semiconductor device 100 in the present example includes an emitter electrode 52 and the active side gate runner 131 which are provided above the upper surface of the semiconductor substrate 10. The emitter electrode 52 and the active side gate runner 131 are provided to be separate from each other.

An interlayer dielectric film is provided between the emitter electrode 52 and the active side gate runner 131, and the upper surface of the semiconductor substrate 10; however, the interlayer dielectric film is omitted in FIG. 2. In the interlayer dielectric film in the present example, a contact portion 54 is provided to pass through the interlayer dielectric film. The contact portion 54 may have a contact hole provided in the interlayer dielectric film and a conductive member with which the contact hole is filled. In FIG. 2, each contact portion 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is connected to the emitter region 12, the contact region 15, and the base region 14 at the upper surface of the semiconductor substrate 10, through the contact portion 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active side gate runner 131 is connected to the gate trench portion 40 through the contact hole provided in the interlayer dielectric film. The active side gate runner 131 may be connected to a gate conductive portion of the gate trench portion 40 at an edge portion 41 of the gate trench portion 40 in the Y axis direction. The active side gate runner 131 is not connected to the dummy conductive portion in the dummy trench portion 30.

The emitter electrode 52 is formed of a material containing metal. FIG. 2 shows a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like, below a region formed of aluminum or the like. Further, a plug, which is formed by embedding tungsten or the like so as to be in contact with the barrier metal and aluminum or the like, may be included in the contact hole.

The well region 11 is provided to overlap with the active side gate runner 131. The well region 11 is provided to extend with a predetermined width even in a range that does not overlap with the active side gate runner 131. The well region 11 in the present example is provided to be spaced apart from an end of the contact portion 54 in the Y axis direction toward the active side gate runner 131. The well region 11 is a region of a second conductivity type having a higher doping concentration than that of the base region 14. The base region 14 in the present example is of the P type, and the well region 11 is of the P+ type.

Each of the transistor portion 70 and the diode portion 80 has a plurality of trench portions arrayed in an array direction. In the transistor portion 70 in the present example, one or more gate trench portions 40 and one or more dummy trench portions 30 are alternately provided along the array direction. In the diode portion 80 in the present example, a plurality of dummy trench portions 30 are provided along the array direction. In the diode portion 80 in the present example, the gate trench portion 40 is not provided.

The gate trench portion 40 in the present example may have two linear parts 39 extending along the extension direction perpendicular to the array direction (parts of a trench which are linear along the extension direction), and the edge portion 41 connecting the two linear parts 39. The extension direction in FIG. 2 is the Y axis direction.

At least a part of the edge portion 41 is preferably provided in a curved shape in the top view. By the edge portion 41 connecting end portions of the two linear parts 39 in the Y axis direction, it is possible to reduce the electric field strength at the end portions of the linear parts 39.

In the transistor portion 70, the dummy trench portions 30 are provided between the respective linear parts 39 of the gate trench portions 40. Between the respective linear parts 39, one dummy trench portion 30 may be provided, or the plurality of dummy trench portions 30 may be provided. The dummy trench portion 30 may have a linear shape extending in the extension direction, or may have linear parts 29 and an edge portion 31 similarly to the gate trench portion 40.

A diffusion depth of the well region 11 may be deeper than depths of the gate trench portion 40 and the dummy trench portion 30. The end portions in the Y axis direction of the gate trench portion 40 and the dummy trench portion 30 are provided in the well region 11 in the top view. In other words, at the end portion of each trench portion in the Y axis direction, a bottom portion of each trench portion in the depth direction is covered with the well region 11. With this configuration, the electric field strength at the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extension direction (the Y axis direction) along the trench, at the upper surface of the semiconductor substrate 10. In the present example, a mesa portion 60 is provided in the transistor portion 70, and a mesa portion 61 is provided in the diode portion 80. As merely referred to as the mesa portion in the present specification, it indicates each of the mesa portion 60 and the mesa portion 61.

Each mesa portion is provided with the base region 14. In the mesa portion, a region arranged to be closest to the active side gate runner 131, in the base region 14 exposed to the upper surface of the semiconductor substrate 10, is set as a base region 14-e. While FIG. 2 shows the base region 14-e arranged at one end portion of each mesa portion in the extension direction, the base region 14-e is also arranged at another end portion of each mesa portion. Each mesa portion may be provided with at least one of the emitter region 12 of a first conductivity type, or the contact region 15 of the second conductivity type in a region sandwiched between the base regions 14-e in the top view. In the present example, the emitter region 12 is of the N+ type, and the contact region 15 is of the P+ type with a higher concentration than that of the base region 14. The emitter region 12 and the contact region 15 may be provided between the base region 14 and the upper surface of the semiconductor substrate 10 in the depth direction.

The mesa portion 60 of the transistor portion 70 has the emitter region 12 exposed to the upper surface of the semiconductor substrate 10. The emitter region 12 is provided in contact with the gate trench portion 40. The mesa portion 60 in contact with the gate trench portion 40 may be provided with the contact region 15 exposed to the upper surface of the semiconductor substrate 10.

The emitter region 12 in the mesa portion 60 is provided in contact with the gate trench portion 40. The emitter region 12 may be in contact with, or may not be in contact with the dummy trench portion 30. The emitter region 12 is also provided in a region which overlaps with the contact portion 54.

The contact region 15 in the mesa portion 60 is provided in the region which overlaps with the contact portion 54. The contact region 15 may be in contact with, or may not be in contact with the gate trench portion 40. The contact region 15 may be in contact with, or may not be in contact with the dummy trench portion 30.

In the example of FIG. 2, the emitter region 12 in the mesa portion 60 is provided from one trench portion in the X axis direction to another trench portion. The contact region 15 in the mesa portion 60 may also be provided from one trench portion in the X axis direction to another trench portion. The contact region 15 may not be in contact with either of two trench portions which sandwich the mesa portion 60. In this case, the base region 14 may be provided between the contact region 15 and the trench portion.

In the example of FIG. 2, the contact region 15 and the emitter region 12 in the mesa portion 60 are alternately arranged along the extension direction of the trench portion (the Y axis direction). In another example, the contact region 15 and the emitter region 12 in the mesa portion 60 may be provided in a stripe shape along the extension direction of the trench portion (the Y axis direction). For example, the emitter region 12 is provided in a region in contact with the trench portion, and the contact region 15 is provided in a region sandwiched between the emitter regions 12. In addition, the mesa portion 60 may be provided with the emitter region 12 instead of the contact region 15. For example, the emitter region 12 may be provided in an entire region sandwiched between the base regions 14-e in the Y axis direction.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged in the entire region sandwiched between the contact regions 15.

The contact portion 54 is provided above each mesa portion. The contact portion 54 is arranged in the region sandwiched between the base regions 14-e. The contact portion 54 in the present example is provided above each region of the contact region 15, the base region 14, and the emitter region 12. The contact portion 54 is not provided in regions corresponding to the base region 14-e and the well region 11. The contact portion 54 may be arranged at the center of the mesa portion 60 in the array direction (the X axis direction).

In the diode portion 80, a cathode region 82 of the N+ type is provided in a region adjacent to the lower surface of the semiconductor substrate 10. At the lower surface of the semiconductor substrate 10, the collector region 22 of the P+ type may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged to be spaced apart from the well region 11 in the Y axis direction. With this configuration, the distance between a region of the P type (the well region 11) having a comparatively high doping concentration and formed up to the deep position, and the cathode region 82 is ensured, so that a breakdown voltage can be improved. An end portion of the cathode region 82 in the Y axis direction in the present example is arranged to be spaced apart from the well region 11 farther than an end portion of the contact portion 54 in the Y axis direction. In another example, the end portion of the cathode region 82 in the Y axis direction may be arranged between the well region 11 and the contact portion 54.

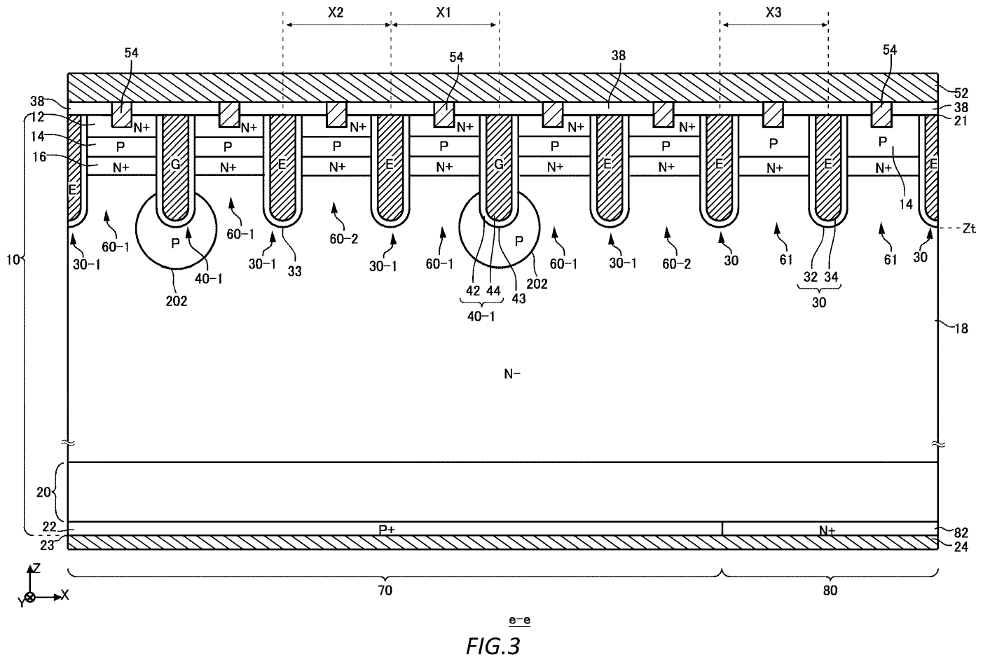

FIG. 3 is a view showing an example of a cross section e-e in FIG. 2. The cross section e-e is an XZ plane passing through an emitter region 12 and the cathode region 82. The semiconductor device 100 in the present example includes the semiconductor substrate 10, an interlayer dielectric film 38, the emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 is provided with the contact portion 54 described with reference to FIG. 2.

The contact portion 54 is provided to pass through the interlayer dielectric film 38. The contact portion 54 may be formed of a metal different from that of the emitter electrode 52. The contact portion 54 may contain tungsten. A bottom portion of the contact portion 54 may be provided with a barrier metal layer containing at least one of a titanium film or a titanium nitride film. The contact portion 54 may be provided up to an upper surface 21 of the semiconductor substrate 10, or may be provided up to an inside of the semiconductor substrate 10. In the example of FIG. 3, the contact portion 54 is a contact trench provided from the upper surface 21 of the semiconductor substrate 10 to an inside of each mesa portion. This makes it possible to increase a contact area between the contact portion 54 and the semiconductor substrate 10. In the cross section, a lower end of the contact portion 54 of the transistor portion 70 is in contact with the emitter region 12. In the cross section, a lower end of the contact portion 54 of the diode portion 80 is in contact with the base region 14.

The emitter electrode 52 is provided above the interlayer dielectric film 38. The emitter electrode 52 is connected to the semiconductor substrate 10 via the contact portion 54. The collector electrode 24 is provided at the lower surface 23 of the semiconductor substrate 10. The emitter electrode 52 and the collector electrode 24 are formed of a metal material such as aluminum. In the present specification, a direction (the Z axis direction) in which the emitter electrode 52 is connected to the collector electrode 24 is referred to as the depth direction. The semiconductor substrate 10 includes a drift region 18 of the N type or the N-type. The drift region 18 is provided in each of the transistor portion 70 and the diode portion 80.

In the mesa portion 60 of the transistor portion 70, the emitter region 12 of the N+ type and the base region 14 of the P type are provided in order starting from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed to the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 in the present example is provided in contact with the emitter region 12. The base region 14 may be in contact with the trench portions on both sides of the mesa portion 60.

The accumulation region 16 is provided below the base region 14. The accumulation region 16 is a region of the N+ type having a higher doping concentration than that of the drift region 18. That is, the accumulation region 16 has a higher donor concentration than that of the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover an entire lower surface of the base region 14 in each mesa portion 60.

In the mesa portion 61 of the diode portion 80, the base region 14 of the P type is provided in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. A doping concentration of the buffer region 20 is higher than the doping concentration of the drift region 18. The buffer region 20 may have a concentration peak having a higher doping concentration than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may have two or more concentration peaks in the depth direction (the Z axis direction) of the semiconductor substrate 10. The concentration peak of the buffer region 20 may be provided, for example, at the same depth position as that of a chemical concentration peak of hydrogen (a proton) or phosphorous. The buffer region 20 may function as a field stopper layer which prevents a depletion layer expanding from a lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. It should be noted that an element serving as a donor and an acceptor in each region is not limited to the example described above. The collector region 22 and the cathode region 82 are exposed to the lower surface 23 of the semiconductor substrate 10 and are connected to the collector electrode 24

The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided at the upper surface 21 side of the semiconductor substrate 10. Each trench portion passes through the base region 14, and is provided from the upper surface 21 of the semiconductor substrate 10 to a region below the base region 14. In a region where at least any of the emitter region 12, the contact region 15, or the accumulation region 16 is provided, each trench portion also passes through the doping regions of these. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

As described above, the transistor portion 70 is provided with the gate trench portion 40 and the dummy trench portion 30. The diode portion 80 is provided with the dummy trench portion 30, and is not provided with the gate trench portion 40. A boundary between the diode portion 80 and the transistor portion 70 in the X axis direction, in the present example, is a boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor at the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 in the present example are covered with the interlayer dielectric film 38 on the upper surface 21 of the semiconductor substrate 10. It should be noted that bottom portions of the dummy trench portion 30 and the gate trench portion 40 may have curved surfaces which are convex downward (curved shapes in the cross sections). In the present specification, a depth position of a lower end 43 of the gate trench portion 40 is set as Zt.

The semiconductor device 100 in the present example includes a floating region 202 of the P type provided below the lower end 43 of the gate trench portion 40. The lower end 43 of the gate trench portion 40 refers to a part, in the gate trench portion 40, which is closest to the lower surface 23 of the semiconductor substrate 10. In the example of FIG. 3, the lower end 43 of the gate trench portion 40 is arranged at the center of the gate trench portion 40 in the X axis direction. In addition, a lower end 33 of the dummy trench portion 30 refers to a part, in the dummy trench portion 30, which is closest to the lower surface 23 of the semiconductor substrate 10. In the example of FIG. 3, the lower end 33 of the dummy trench portion 30 is arranged at the center of the dummy trench portion 30 in the X axis direction.

At least a part of the floating region 202 is provided at a position that overlaps with the lower end 43 in the top view, and is arranged below the lower end 43 in the Z axis direction. The floating region 202 may include a part that does not overlap with the lower end 43 in the top view. The floating region 202 may include a part provided above the lower end 43. The floating region 202 may be in contact with the lower end 43, or may be spaced apart from the lower end 43. In the example of FIG. 3, the floating region 202 is in contact with the entire curved surface part including the lower end 43, in the gate trench portion 40. The floating region 202 may be formed, after forming a trench structure of the gate trench portion 40 and before forming the gate conductive portion 44, by implanting the dopant of the P type in a vicinity of a lower end of the trench structure.

The floating region 202 is electrically floating with respect to an electrode of metal, or polysilicon, or the like. At least one of a region of the N type or a dielectric film is arranged between the floating region 202 and the electrode. In other words, the floating region 202 and the electrode are not connected to each other by a region of the P type or a conductive material. A doping concentration of the floating region 202 may be lower than or equal to the doping concentration of the base region 14, or may be higher than the doping concentration of the base region 14. The doping concentration of the floating region 202 in the present example is higher than the doping concentration of the base region 14. The doping concentration may be higher than or equal to 1×10¹⁵ cm⁻³ and lower than or equal to 1×10¹⁷ cm⁻³.

The floating region 202 is arranged to be spaced apart from the base region 14. A region of the N type (in the present example, at least one of the accumulation region 16 or the drift region 18) is provided between the floating region 202 and the base region 14.

In the present specification, among the gate trench portions 40, the one that has the floating region 202 arranged below is referred to as a first gate trench portion 40-1. In addition, among the dummy trench portions 30, the one that is arranged side by side with the first gate trench portion 40-1 in the X axis direction at the upper surface 21, is referred to as a first dummy trench portion 30-1. The first gate trench portion 40-1 and the first dummy trench portion 30-1 are two trench portions adjacent to each other in the X axis direction. In the present example, the first dummy trench portions 30-1 are arranged on both sides of the first gate trench portion 40-1 in the X axis direction. In addition, in the mesa portions 60, the one that is sandwiched between the first gate trench portion 40-1 and the first dummy trench portion 30-1 is referred to as a first mesa portion 60-1. Among the mesa portions 60, the one that is sandwiched between two dummy trench portions 30 is referred to as a second mesa portion 60-2. The second mesa portion 60-2 may have the same structure as that of the first mesa portion 60-1.

Each transistor portion 70 has one or more first gate trench portions 40-1. Each transistor portion 70 may have a plurality of first gate trench portions 40-1. In each transistor portion 70, 50% or more of the gate trench portions 40 may be the first gate trench portions 40-1, 80% or more of the gate trench portions 40 may be the first gate trench portions 40-1, or all of the gate trench portions 40 may be the first gate trench portions 40-1.

The floating region 202 is arranged below the lower end 43 of the first gate trench portion 40-1, and does not extend to a region below the lower end 33 of the adjacent first dummy trench portion 30-1. The lower end 33 is in contact with a region of the N type (in the present example, the drift region 18). In addition, at the upper surface 21 side of the semiconductor substrate 10, below the lower end 33, no region of the P type is provided, and a region of the N type (the drift region 18 in the present example) is provided.

By providing the floating region 202, it is possible to prevent electrons from flowing to the lower end 43 of the first gate trench portion 40-1 when the transistor portion 70 is turned on, and to cause a depletion layer to remain in a vicinity of the lower end 43. Therefore, it is possible to reduce a reverse recovery dV/dt. The reverse recovery dV/dt is a slope of a time waveform of an anode-cathode voltage at a time of the reverse recovery of the diode portion 80. In addition, when the semiconductor device 100 is used in a circuit such as a three-phase inverter, it is possible to decrease a tail of a voltage waveform of the IGBT provided in opposing arms. Therefore, it is possible to improve a trade-off characteristic between a turn-on loss and the reverse recovery dV/dt.

On the other hand, when the floating region 202 extends to a region below the lower end 33 of the first dummy trench portion 30-1, in a case where a channel is formed in the base region 14 of the first mesa portion 60-1 and an electron current flows, it becomes difficult for the electron current to flow to the collector region 22. Therefore, a snapback may occur when the transistor portion 70 is turned on. In addition, a turn-on time of the transistor portion 70 may become longer. In the semiconductor device 100 in the present example, the floating region 202 does not extend to the region below the lower end 33 of the first dummy trench portion 30-1. Therefore, in the case where a channel is formed in the base region 14 of the first mesa portion 60-1 and an electron current flows, it becomes easy for the electron current to flow to the collector region 22. This makes it possible to suppress an occurrence of the snapback, and makes it possible to reduce a turn-on delay.

The floating region 202 in the present example is arranged not to overlap the first dummy trench portion 30-1 in the top view. The floating region 202 may be arranged not to be in contact with the first dummy trench portion 30-1. In the present example, a region of the N type is arranged between the floating region 202 and the first dummy trench portion 30-1. The floating region 202 may be arranged to overlap with the first mesa portion 60-1 in the top view. The first mesa portion 60-1 may have a region which does not overlap with the floating region 202 in the top view. In the first mesa portion 60-1 in the present example, a region which is in contact with the first dummy trench portion 30-1 does not overlap with the floating region 202. The floating region 202 may extend to a position that overlaps with the contact portion 54 of the first mesa portion 60-1, or may be arranged not to overlap.

The floating region 202 is provided to extend in the Y axis direction in the top view. A length of the floating region 202 in the Y axis direction may be 50% or more of a length of the linear part 39 of the first gate trench portion 40-1 in the Y axis direction, may be 70% or more, or may be 90% or more. When the floating region 202 is provided over the entire first gate trench portion 40-1, an end portion of the floating region 202 in the Y axis direction is positioned below the base region 14-e.

An interval in the X axis direction between the first gate trench portion 40-1 and the first dummy trench portion 30-1 is set as X1. An interval between the trench portions is a distance between the centers of the trench portions in the X axis direction. An interval in the X axis direction between the two dummy trench portions 30 in the transistor portion 70 is set as X2. In the present example, an interval between the two first dummy trench portions 30-1 is X2. The interval X1 and the interval X2 may be the same as each other. An interval in the X axis direction between the two dummy trench portions 30 in the diode portion 80 is set as X3. The interval X1, the interval X2, and the interval X3 may be the same.

In at least one transistor portion 70 which is arranged to be sandwiched between two diode portions 80 in the X axis direction, the intervals between all of the trench portions may be the same. In addition, the intervals between all of the trench portions in the semiconductor device 100 may be the same.

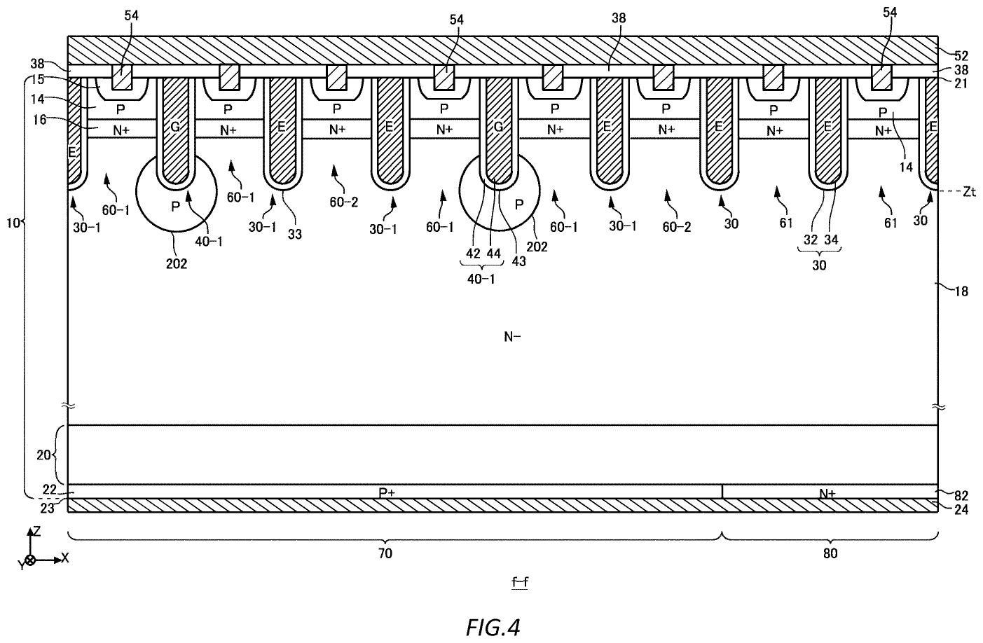

FIG. 4 is a view showing an example of a cross section f-f in FIG. 2. The cross section f-f is an XZ plane passing through the contact region 15 and the cathode region 82. The semiconductor device 100 in the cross section f-f has the contact region 15, instead of the emitter region 12 of the mesa portion 60, in the structure of the semiconductor device 100 in the cross section e-e. In addition, in the mesa portion 61 as well, the contact region 15 is provided. Other structures are similar to that of the semiconductor device 100 in the cross section e-e.

The contact region 15 is exposed to the upper surface 21 of the semiconductor substrate 10. The contact region 15 is provided between the upper surface 21 and the base region 14. The contact region 15 in the present example is not in contact with the trench portions on both sides, in each mesa portion. In the example of FIG. 4, the base region 14 is provided between the contact region 15 and each trench portion. The contact region 15 in the present example is connected to the emitter electrode 52 via the contact portion 54. The contact region 15 may be provided with a trench portion into which the contact portion 54 is inserted. In the cross section, the lower ends of the contact portions 54 of the transistor portion 70 and the diode portion 80 are in contact with the contact region 15.

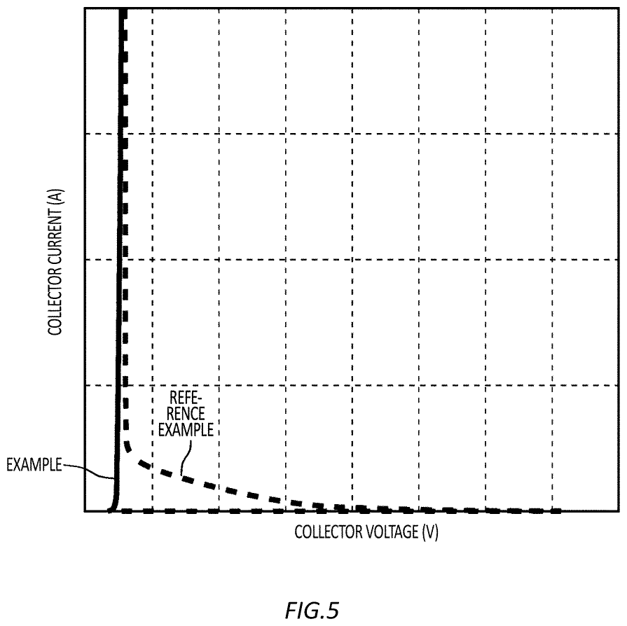

FIG. 5 is a diagram showing a collector voltage-collector current characteristic, in an Example and a reference example. The reference example is an example in which the floating region 202 is caused to extend to a region below the lower end 33 of the first dummy trench portion 30-1. The Example is the semiconductor device 100 described with reference to FIG. 1 to FIG. 4.

In the reference example, the floating region 202 makes it difficult for the electron current of the first mesa portion 60-1 to flow to the collector region 22. Therefore, in the reference example, as shown in FIG. 5, there occurs the snapback in which almost no collector current flows until the collector voltage becomes greater than a predetermined voltage. In contrast with this, in the semiconductor device 100 according to the Example, the electron current of the first mesa portion 60-1 easily flows to the collector region 22. Therefore, the snapback does not occur.

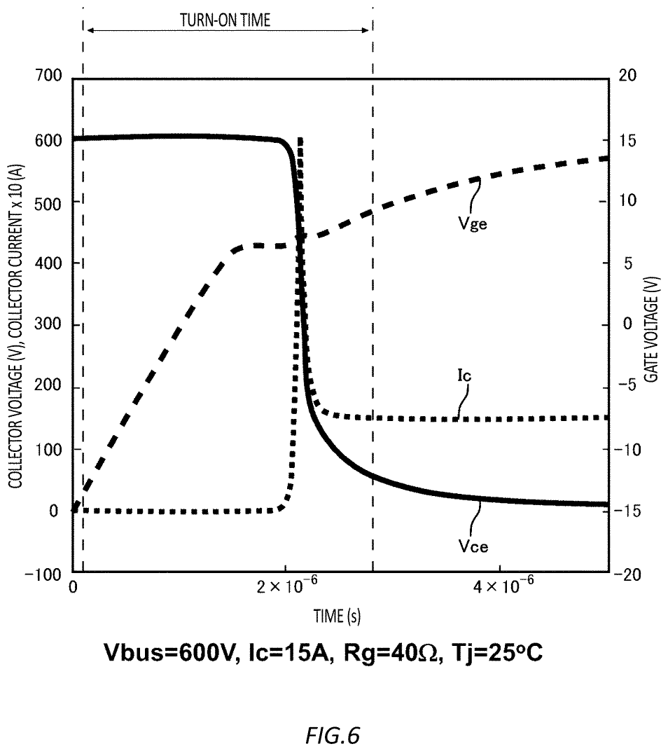

FIG. 6 is a diagram showing a measurement example of a voltage and a current of the semiconductor device of the reference example. The semiconductor device of the reference example in FIG. 6 has a structure similar to that of the semiconductor device of the reference example in FIG. 5. FIG. 6 shows time waveforms of a collector voltage Vce, a collector current Ic, and a gate voltage Vge of the semiconductor device. In FIG. 6, Vbus represents a voltage of bus wiring that is connected to the collector of the semiconductor device, Ic represents a steady-state value of the collector current, Rg represents a gate resistance, and Tj represents a temperature of a measurement environment.

In FIG. 6, a timing when a predetermined on-voltage is applied to a gate of the semiconductor device is set as reference time zero. In addition, a time until the collector voltage Vce is decreased to 10% of a voltage value (600 V) in an off state is set as a turn-on time of the semiconductor device.

As a gate capacitance is charged, the gate voltage Vge is increased. In the present example, when the gate voltage Vge becomes about 7.5 V, a channel is formed in the base region 14. Note that in the reference example, it is difficult for the electron current of the first mesa portion 60-1 to flow to the collector region 22, and thus a rise of the collector current Ic is delayed, and in addition, a fall of the collector voltage Vce is delayed. Therefore, the turn-on time becomes comparatively long, which increases a loss at a time of a turn-on.

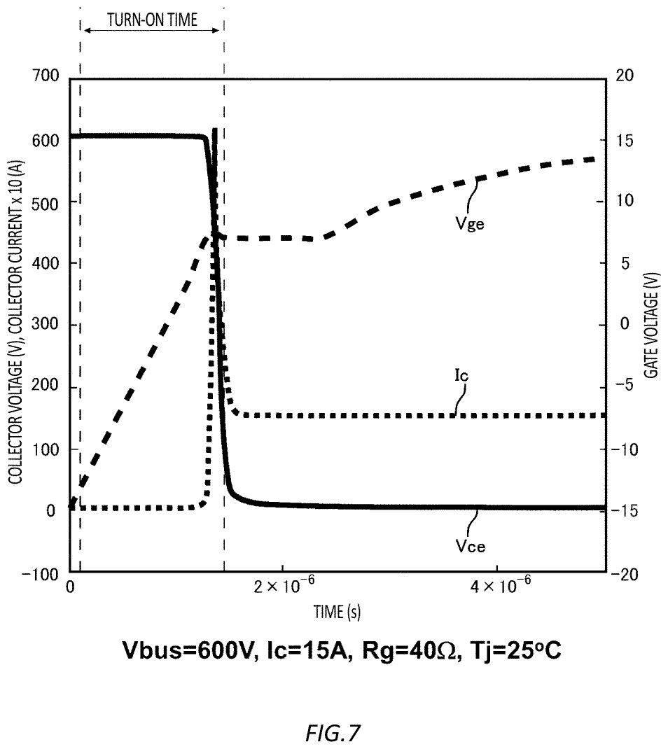

FIG. 7 is a diagram showing a measurement example of a voltage and a current of the semiconductor device of an Example. The semiconductor device of the Example in FIG. 7 is the semiconductor device 100 described with reference to FIG. 1 to FIG. 4. In the Example, the electron current of the first mesa portion 60-1 flows easily to the collector region 22. Therefore, the delay in the rise of the collector current Ic and the fall of the collector voltage Vce are small. In this manner, the turn-on time becomes comparatively short, which makes it possible to reduce a loss at a time of a turn-on.

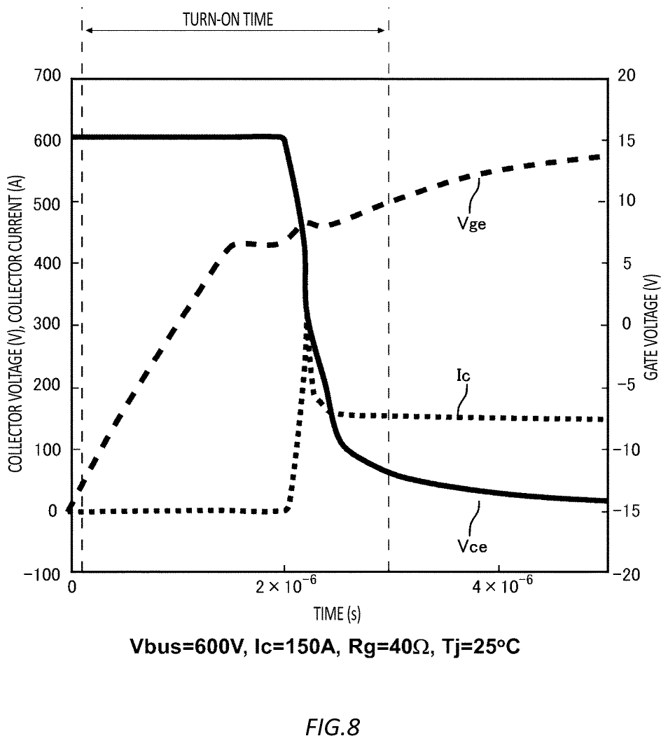

FIG. 8 is a diagram showing another measurement example of the voltage and the current of the semiconductor device of a reference example. In the present example, the steady-state value of the collector current Ic (150 A) is different from the steady-state value of the collector current Ic (15 A) in the reference example of FIG. 6. Other conditions are similar to those in the reference example of FIG. 6. In the reference example of FIG. 8 as well, the rise of the collector current Ic is delayed, and in addition, the fall of the collector voltage Vce is delayed. Therefore, the turn-on time becomes comparatively long, which increases a loss at a time of a turn-on.

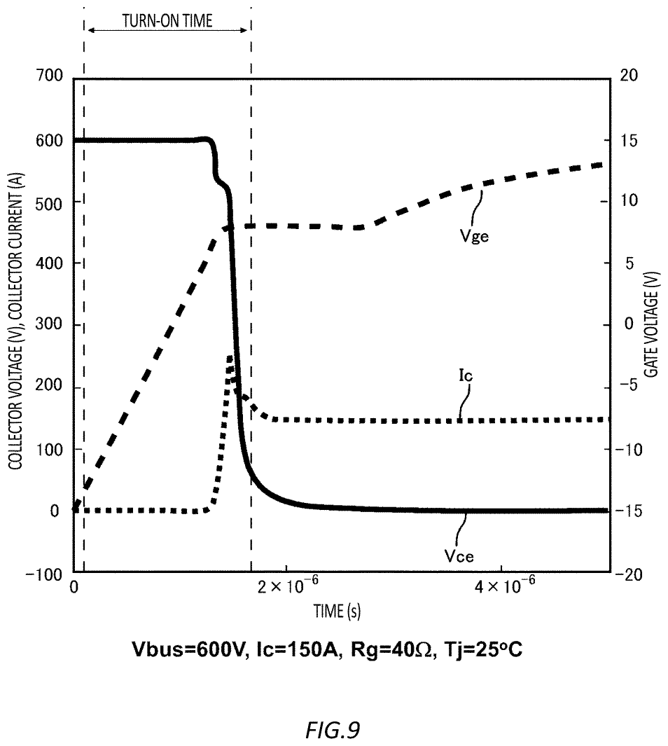

FIG. 9 is a diagram showing another measurement example of the voltage and the current of the semiconductor device of an Example. In the present example, the steady-state value of the collector current Ic (150 A) is different from the steady-state value of the collector current Ic (15 A) in the Example of FIG. 7. Other conditions are similar to those in the Example of FIG. 7. In the Example of FIG. 9 as well, the delay in the rise of the collector current Ic and the fall of the collector voltage Vce are small. In this manner, the turn-on time becomes comparatively short, which makes it possible to reduce a loss at a time of a turn-on.

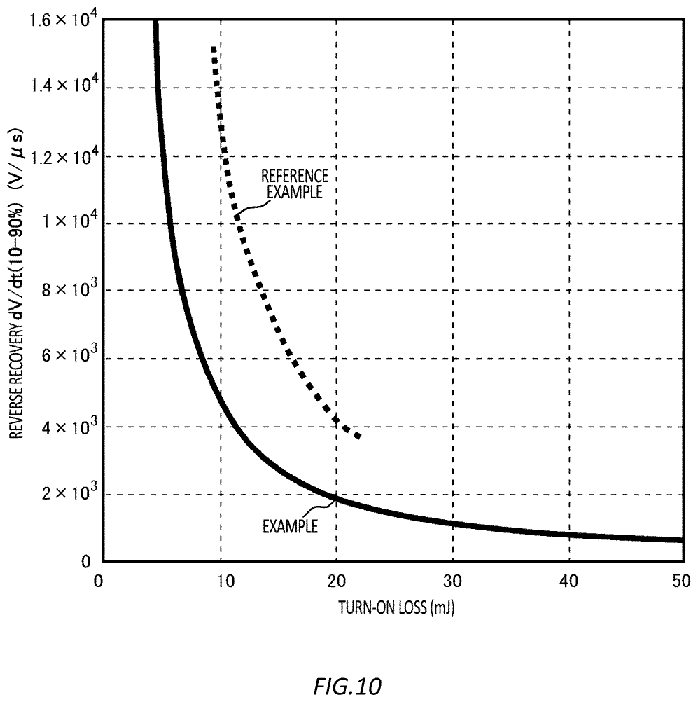

FIG. 10 is a diagram showing a trade-off characteristic between a turn-on loss and a reverse recovery dV/dt in a reference example and an Example. FIG. 10 shows the trade-off relationship in which the turn-on loss is increased when the reverse recovery dV/dt is reduced.

The reference example in FIG. 10 is a semiconductor device which does not have the floating region 202. The semiconductor device of the Example is the semiconductor device 100 described with reference to FIG. 1 to FIG. 4. The semiconductor device 100 of the Example has the floating region 202, thereby improving the trade-off characteristic. For example, when the reverse recovery dV/dt is set to be the same, the turn-on loss is smaller in the Example than in the reference example.

As described with reference to FIG. 10, with the semiconductor device 100, it is possible to improve the trade-off characteristic between the turn-on loss and the reverse recovery dV/dt. As described with reference to FIG. 5, with the semiconductor device 100, it is possible to suppress the snapback. As described with reference to FIG. 6 to FIG. 9, with the semiconductor device 100, it is possible to decrease the turn-on delay in the transistor portion 70.

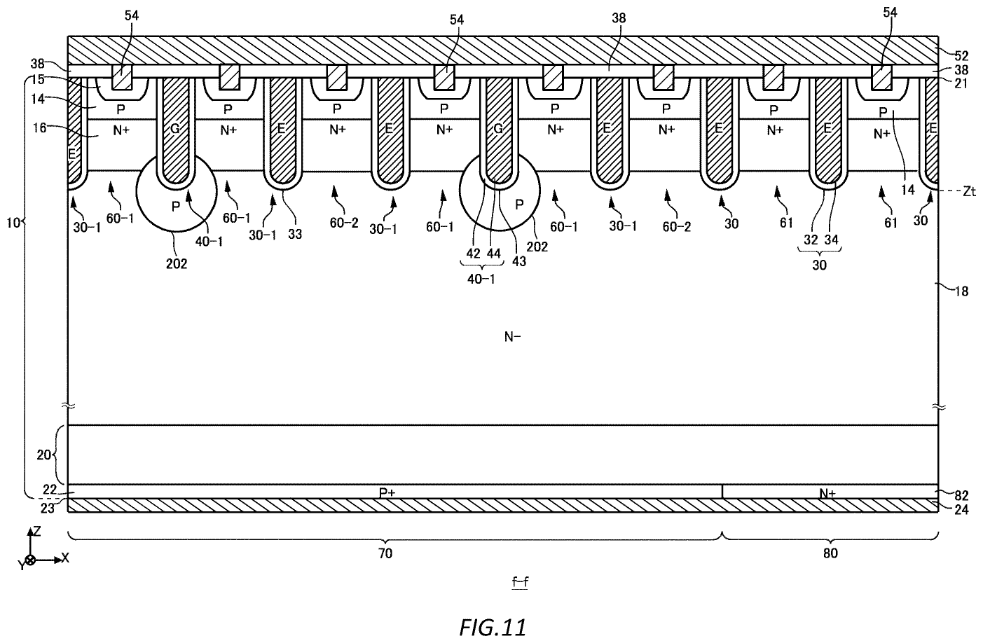

FIG. 11 is a view showing another example of the cross section f-f. The semiconductor device 100 in the present example is different from the semiconductor device 100 shown in FIG. 3 and FIG. 4 in the structure of the accumulation region 16. Other structures are similar to those of the semiconductor device 100 in any aspect described in the present specification.

The accumulation region 16 in the present example is in contact with the floating region 202. The accumulation region 16 may be in contact with, or may not be in contact with the base region 14. In each mesa portion, a lower end of the accumulation region 16 may be provided at the same depth position. The lower end of the accumulation region 16 may be arranged to be closer to the upper surface 21 side than the lower end 43 of the first gate trench portion 40-1, may be arranged to be closer to the lower surface 23 than the lower end 43, or may be arranged at the same depth as that of the lower end 43. In the present example, the lower end of the accumulation region 16 is arranged above a lower end of the floating region 202.

According to the present example, the accumulation region 16 having a high concentration is arranged in a vicinity of the floating region 202, and thus it is possible to suppress an excessive diffusion of the dopant of the P type in the floating region 202, and it is possible to suppress the entire first mesa portion 60-1 being covered by the floating region 202. For example, a region of the N type easily remains in a vicinity of the first dummy trench portion 30-1. Therefore, it becomes easy to further suppress the occurrence of the snapback or the like.

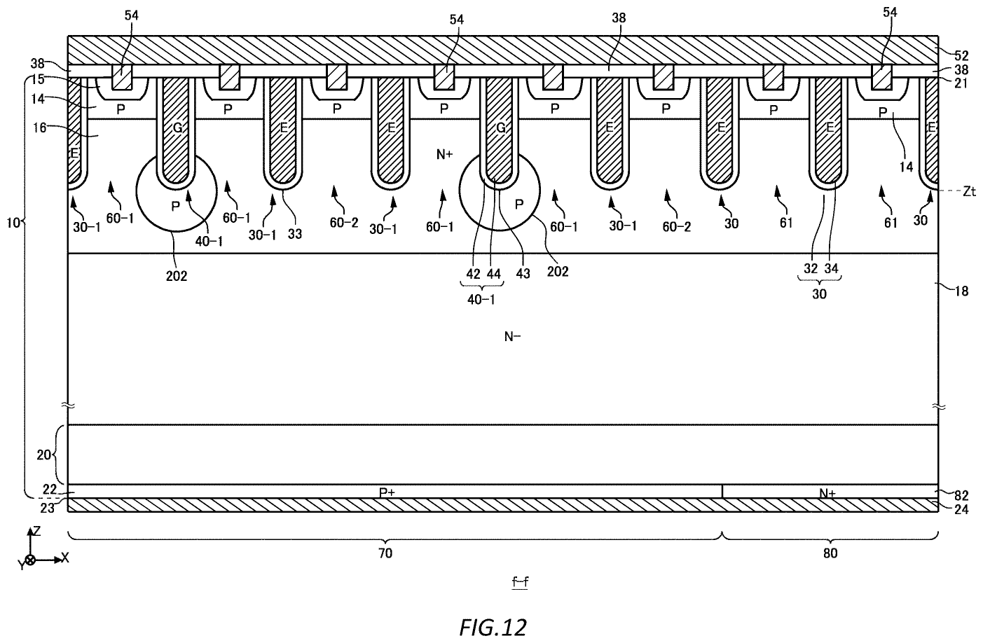

FIG. 12 is a view showing another example of the cross section f-f. The semiconductor device 100 in the present example is different from the semiconductor device 100 shown in FIG. 11 in the structure of the accumulation region 16. Other structures are similar to those of the semiconductor device 100 in any aspect described in the present specification.

In the present example, the lower end of the accumulation region 16 is arranged below the lower end of the floating region 202. The floating region 202 in the present example is surrounded by the accumulation region 16, except for a part in contact with the trench portion. The lower end of the accumulation region 16 may be arranged at the upper surface 21 side of the semiconductor substrate 10. A distance in the Z axis direction between the lower end of the floating region 202 and the lower end of the accumulation region 16 may be 10 μm or less, may be 5 μm or less, or may be 3 μm or less.

According to the present example, the floating region 202 is surrounded by the accumulation region 16. Therefore, an excessive diffusion of the dopant of the P type in the floating region 202, for the entire first mesa portion 60-1 to be covered by the floating region 202, can be suppressed. For example, a region of the N type easily remains in a vicinity of the first dummy trench portion 30-1. Therefore, it becomes easy to further suppress the occurrence of the snapback or the like.

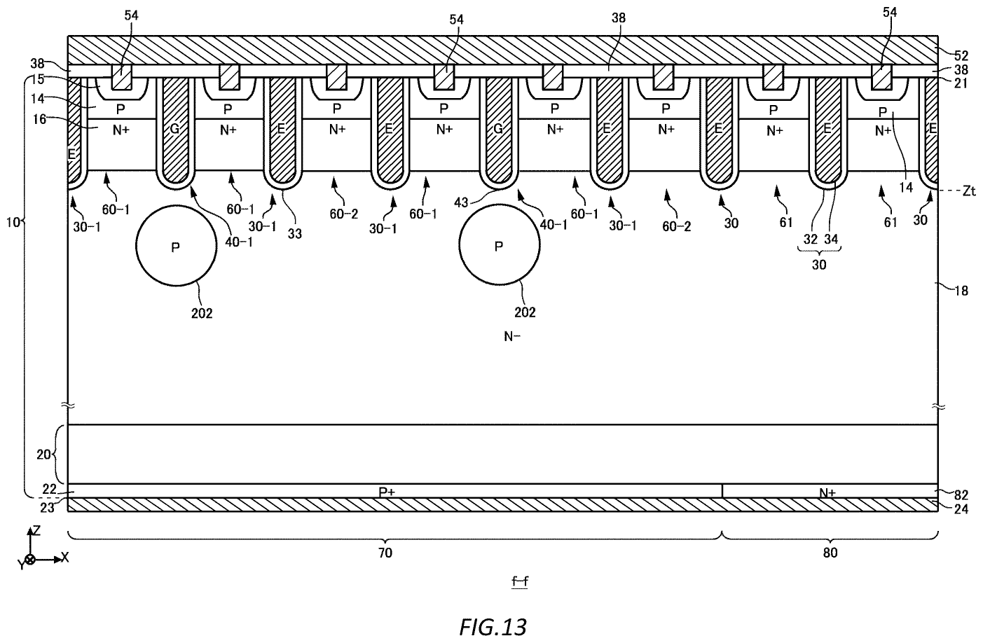

FIG. 13 is a view showing another example of the cross section f-f. The semiconductor device 100 in the present example is different from the semiconductor device 100 in other examples in the arrangement of the floating regions 202. Other structures are similar to those of the semiconductor device 100 in any aspect described in the present specification.

The floating region 202 in the present example is not in contact with the first gate trench portion 40-1. The floating region 202 is arranged below the lower end 43 of the first gate trench portion 40-1, and is spaced apart from the lower end 43. In the present example as well, the floating region 202 is arranged at the upper surface 21 side of the semiconductor substrate 10. A distance between the floating region 202 and the lower end 43 in the Z axis direction may be 10 μm or less, may be 5 μm or less, or may be 3 μm or less. With the present example, it becomes easy to ensure a path in which the electron current flows from the first mesa portion 60-1 to the collector region 22. Therefore, it is possible to further suppress the occurrence of the snapback or the like.

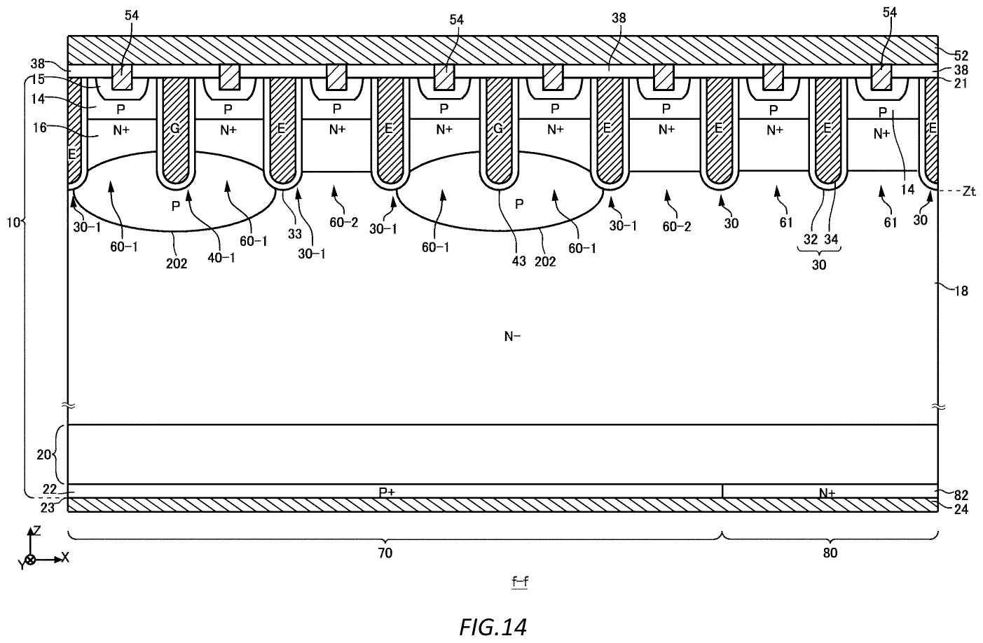

FIG. 14 is a view showing another example of the cross section f-f. The semiconductor device 100 in the present example is different from the semiconductor device 100 in other examples in the arrangement of the floating regions 202. Other structures are similar to those of the semiconductor device 100 in any aspect described in the present specification.

The floating region 202 in the present example is in contact with the first dummy trench portion 30-1. When the first dummy trench portions 30-1 are arranged on both sides of the first gate trench portion 40-1 in the X axis direction, the floating region 202 may be in contact with both of the first dummy trench portions 30-1.

In the present example as well, the floating region 202 does not extend to the region below the lower end 33 of the first dummy trench portion 30-1. The floating region 202 may be in contact with a side wall of the first dummy trench portion 30-1. The side wall is a part of an outer wall part of the first dummy trench portion 30-1 other than the lower end 33. The side wall of the first dummy trench portion 30-1 may be a flat surface part in the outer wall of the first dummy trench portion 30-1. In the present example as well, it is possible to improve the trade-off characteristic described above.

The dummy conductive portion 34 of the first dummy trench portion 30-1 in the present example may be a polysilicon electrode doped with an impurity of the N type. When the dummy conductive portion 34 is polysilicon of the P type, the side wall of the first dummy trench portion 30-1 has the same potential as the floating region 202. In this case, a path in which the electron current flows from the channel is cut off by an equipotential region, and it becomes difficult for the electron current to flow. By causing the dummy conductive portion 34 to be of the N type, the side wall of the first dummy trench portion 30-1 has a different potential from that of the floating region 202. In this case, the path in which the electron current flows remains in a vicinity of the side wall of the first dummy trench portion 30-1. In other words, it is possible to suppress the occurrence of the snapback or the like, and to improve the trade-off characteristic of the semiconductor device 100.

The conductive portions of the trench portions other than the first dummy trench portion 30-1 may also be polysilicon of the N type. A doping concentration of the impurity of the N type in the dummy conductive portion 34 of the first dummy trench portion 30-1 may be higher than a doping concentration of the impurity of the N type in the gate conductive portion 44 of the first gate trench portion 40-1. This makes it easy to ensure a path in which the electron current flows in a vicinity of the side wall of the first dummy trench portion 30-1. In another example, the conductive portions of at least some trench portions of the trench portions other than the first dummy trench portion 30-1 may be polysilicon of the P type. For example, the conductive portion of the first gate trench portion 40-1 may be polysilicon of the P type.

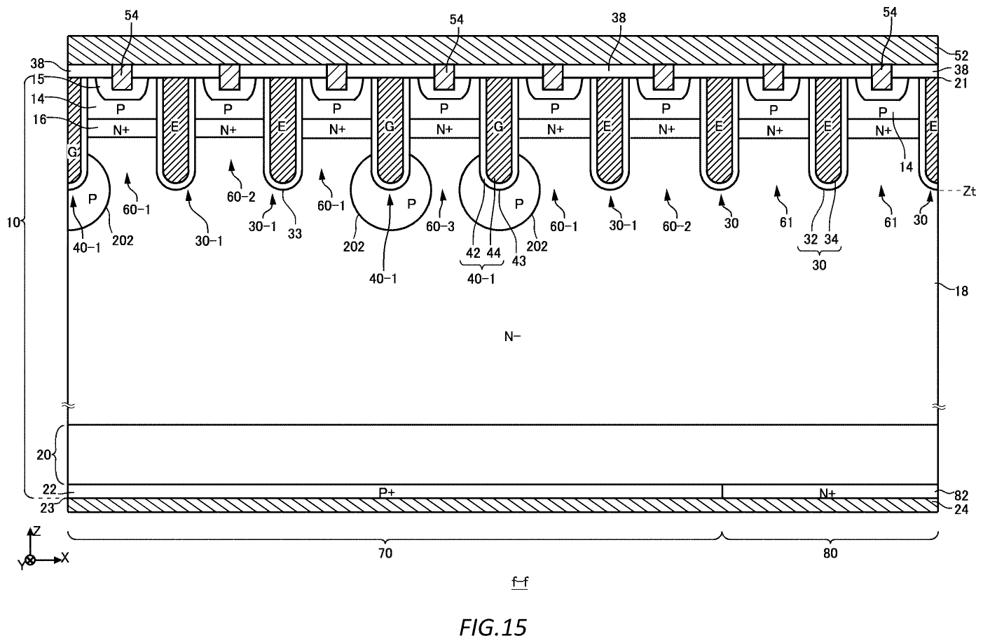

FIG. 15 is a view showing another example of the cross section f-f. The semiconductor device 100 in the present example is different from the semiconductor device 100 in other examples in the arrangement pattern of the trench portions of the transistor portion 70 in the X axis direction. Structures other than the arrangement pattern of the trench portions are similar to those of the semiconductor device 100 in any aspect described in the present specification.

The transistor portion 70 in the present example has two first gate trench portions 40-1 arranged to be adjacent to each other in the X axis direction. As an example, in the transistor portion 70, two first gate trench portions 40-1 and two first dummy trench portions 30-1 are arranged alternately in the X axis direction.

The floating region 202 is arranged below the lower end 43 of each of the first gate trench portions 40-1. The floating regions 202 below the two first gate trench portions 40-1 adjacent to each other in the X axis direction may be separated from each other as shown in FIG. 15, or may be connected to each other.

The mesa portion 60 sandwiched between the two first gate trench portions 40-1 is referred to as a third mesa portion 60-3. The third mesa portion 60-3 may have the same structure as that of the first mesa portion 60-1. In another example, the third mesa portion 60-3 may have a different structure from that of the first mesa portion 60-1. The third mesa portion 60-3 may be sandwiched between the first mesa portions 60-1 in the X axis direction. In the present example, three or more first gate trench portions 40-1 are not arranged continuously, in the X axis direction.

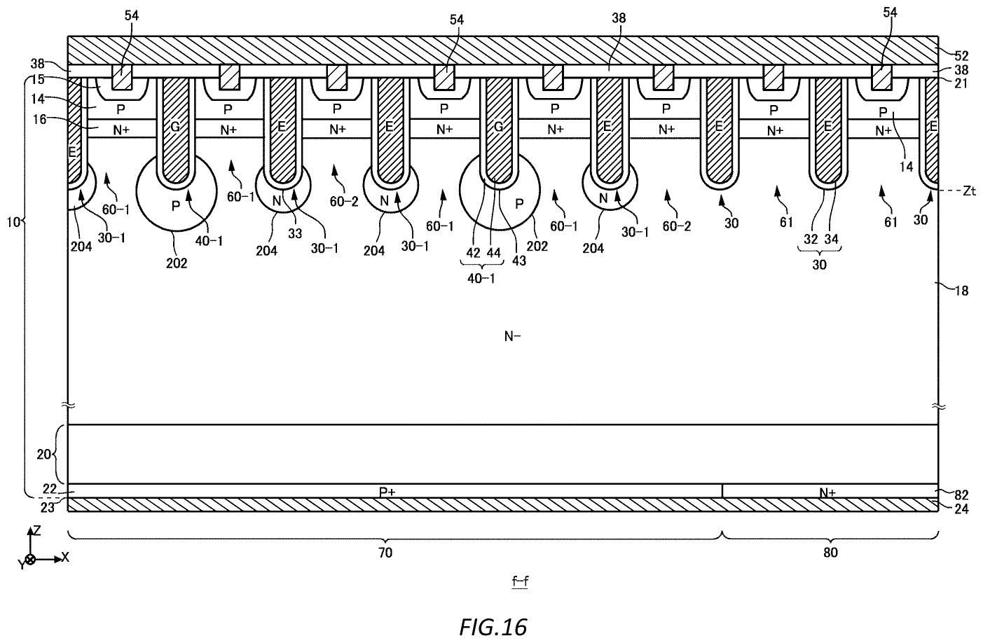

FIG. 16 is a view showing another example of the cross section f-f. The semiconductor device 100 in the present example is different from the semiconductor device 100 in the other examples in that a lower end region 204 is included. Structures other than the lower end region 204 are similar to those of the semiconductor device 100 in any aspect described in the present specification.

The lower end region 204 is a region of the N type which is provided below the lower end 33 of the first dummy trench portion 30-1. A doping concentration of the lower end region 204 is higher than the doping concentration of the drift region 18. The doping concentration of the lower end region 204 may be two times or more of the doping concentration of the drift region 18, may be five times or more, or may be ten times or more. The doping concentration of the lower end region 204 may be higher than, or may be lower than the doping concentration of the floating region 202. By providing the lower end region 204, it is possible to suppress a vicinity of the lower end 33 of the first dummy trench portion 30-1 becoming P type, and it becomes easy to ensure the path for the electron current.

The lower end region 204 may be in contact with, or may be spaced apart from the lower end 33 of the first dummy trench portions 30-1. A lower end of the lower end region 204 may be arranged above, or may be arranged below the lower end of the floating region 202. The lower end region 204 may be spaced apart from, or may be in contact with the accumulation region 16.

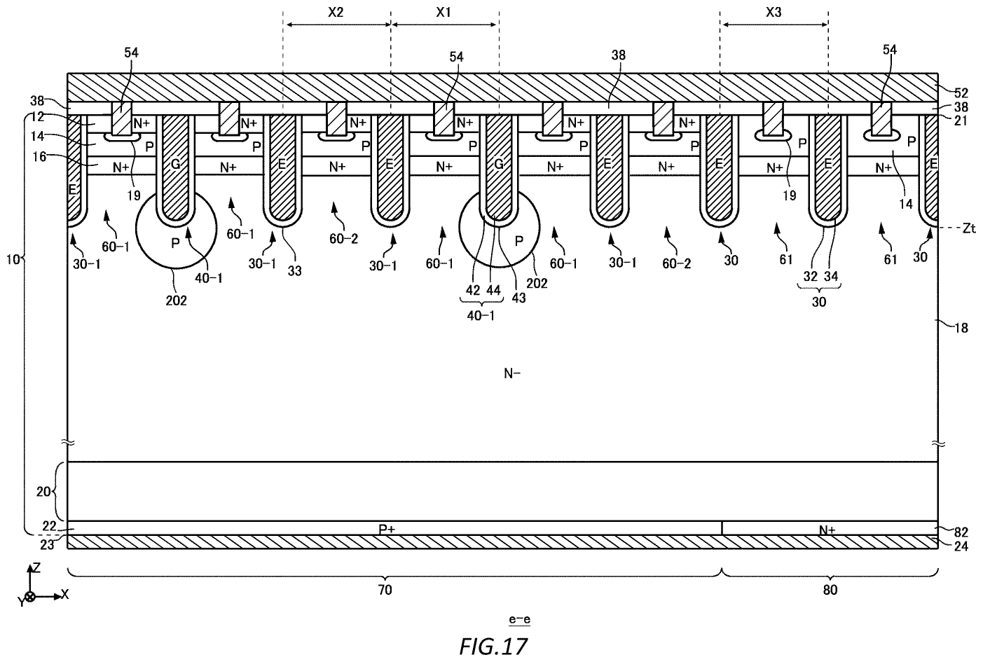

FIG. 17 is a view showing another example of the cross section e-e. The semiconductor device 100 in the present example further includes a contact region 19, with respect to the structure shown in FIG. 3. In addition, the arrangement of the contact portion 54 is different. Other structures are similar to those in the example in FIG. 3.

The contact region 19 is provided in contact with the lower end of the contact portion 54, and is a region of the P+ type with a higher concentration than that of the base region 14. A doping concentration of the contact region 19 may be the same as that of the contact region 15. At least a part of the contact region 19 may be provided inside the base region 14. The contact portion 54 in the transistor portion 70 may be provided to pass through, or may be provided not to pass through the emitter region 12. In the present example, the contact region 19 in the transistor portion 70 is provided below the emitter region 12. In addition, the entire contact region 19 in the diode portion 80 is provided inside the base region 14.

In each mesa portion in the cross section f-f, the contact region 19 may be provided at a depth position similar to that in the cross section e-e. In addition, when the emitter region 12 is provided instead of the contact region 15, the cross section f-f has a structure similar to that of FIG. 17.

While the present invention has been described by way of the embodiments, the technical scope of the present invention is not limited to the above-described embodiments. It is apparent to persons skilled in the art that various alterations or improvements can be made to the above described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” for convenience in the claims, embodiments, or diagrams, it does not necessarily mean that the process must be performed in this order.

What is claimed is:

1. A semiconductor device which includes an IGBT, the semiconductor device comprising:
a semiconductor substrate which has an upper surface and a lower surface, and which is provided with a drift region of a first conductivity type;
a first gate trench portion which is provided at the upper surface of the semiconductor substrate;
a first dummy trench portion which is provided at the upper surface of the semiconductor substrate, and which is arranged side by side with the first gate trench portion at the upper surface;
a first mesa portion which is sandwiched between the first gate trench portion and the first dummy trench portion, inside the semiconductor substrate; and
a floating region of a second conductivity type which is arranged below a lower end of the first gate trench portion, and which does not extend to a region below a lower end of the first dummy trench portion, at an upper surface side of the semiconductor substrate, wherein
the first mesa portion has
an emitter region of the first conductivity type which is provided in contact with the first gate trench portion, and which has a higher concentration than that of the drift region, and
a base region of the second conductivity type which is provided between the emitter region and the drift region, and which is in contact with the first gate trench portion, and
the lower end of the first dummy trench portion is in contact with a region of the first conductivity type.

2. The semiconductor device according to claim 1, wherein
the floating region is not in contact with the lower end of the first gate trench portion.

3. The semiconductor device according to claim 1, wherein
the floating region is in contact with the lower end of the first gate trench portion.

4. The semiconductor device according to claim 1, wherein
the first mesa portion further has an accumulation region of the first conductivity type which is provided between the base region and the drift region, and which has a higher concentration than that of the drift region.

5. The semiconductor device according to claim 4, wherein
the accumulation region is in contact with the floating region.

6. The semiconductor device according to claim 5, wherein
a lower end of the accumulation region is arranged below a lower end of the floating region.

7. The semiconductor device according to claim 5, wherein
a lower end of the accumulation region is arranged above a lower end of the floating region.

8. The semiconductor device according to claim 1, wherein
the first mesa portion further has a contact region of the second conductivity type which is in contact with the upper surface of the semiconductor substrate, and which has a higher concentration than that of the base region.

9. The semiconductor device according to claim 8, wherein
the first mesa portion further has a contact portion which is provided from the upper surface of the semiconductor substrate to an inside of the first mesa portion, and which is filled with a conductive material.

10. The semiconductor device according to claim 9, wherein
a lower end of the contact portion is in contact with the contact region.

11. The semiconductor device according to claim 1, wherein
the first dummy trench portion is provided on each of both sides of the first gate trench portion.

12. The semiconductor device according to claim 1, wherein
the floating region is in contact with a side wall of the first dummy trench portion.

13. The semiconductor device according to claim 12, wherein
the first dummy trench portion has a polysilicon electrode doped with an impurity of the first conductivity type.

14. The semiconductor device according to claim 1, further comprising:
a lower end region of the first conductivity type which is provided in contact with the lower end of the first dummy trench portion, and which has a higher concentration than that of the drift region.

15. The semiconductor device according to claim 1, further comprising:
two dummy trench portions which are provided at the upper surface of the semiconductor substrate, and which are arranged side by side at the upper surface.

16. The semiconductor device according to claim 15, wherein
an interval between the first gate trench portion and the first dummy trench portion is the same as an interval between the two dummy trench portions.

17. The semiconductor device according to claim 1, further comprising:
a plurality of diode portions, each of which is alternately arranged side by side with the IGBT in a first direction, wherein
the IGBT arranged to be sandwiched between the diode portions, has a plurality of trench portions arranged side by side in the first direction, including the first gate trench portion and the first dummy trench portion, and
intervals between the respective trench portions in the plurality of trench portions are the same.

18. The semiconductor device according to claim 1, wherein
the lower end of the first dummy trench portion is positioned at a same depth as that of a part of the floating region.

19. The semiconductor device according to claim 1, wherein
a depth position of the lower end of the first gate trench portion is equal to a depth position of the lower end of the first dummy trench portion.

20. The semiconductor device according to claim 1, wherein
at least a part of a gate conductive portion of the first gate trench portion to which a gate voltage is applied, is positioned at a same depth as that of at least a part of the floating region.

21. The semiconductor device according to claim 9, wherein
a width of the contact portion is smaller than a width of the first mesa portion.
